(19) United States
(12) Patent Application Publication
(10) Pub. No.: US 2006/0125514 A1
(43) Pub. Date: Jun. 15, 2006

(54) Semiconductor integrated circuit having interface circuit containing pull-up resistor and blocking diode, circuit module including such integrated circuit, and electronic apparatus including such circuit modules

(75) Inventor: Susumu Hashimoto, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 11/295,457

(22) Filed: Dec. 7, 2005

(30) Foreign Application Priority Data
Dec. 10, 2004 (JP) 2004-358578

(51) Int. Cl. H03K 19/003

(52) U.S. Cl. 326/21

(57) ABSTRACT

In a semiconductor integrated circuit having an interface circuit adapted to be connected to a power supply line connected to the interface circuit, and a signal line connected to the interface circuit. A pull-up resistor is connected to the power supply line at one terminal thereof. A blocking diode has an anode and a cathode which are connected to the terminal of the pull-up resistor and the signal line, respectively.

### BACKGROUND OF THE INVENTION

1. Field of the Invention

The present invention relates to a semiconductor integrated circuit having an interface circuit containing a pull-up resistor and a blocking diode, a circuit module including such a semiconductor integrated circuit, and an electronic apparatus including such circuit modules.

2. Description of the Related Art

An electronic apparatus, such as an electrostatic copier, a printer, and so on, includes a plurality of circuit modules, and each of the module circuits includes at least one semiconductor integrated circuit having an interface circuit incorporated therein. Among the circuit modules, an interface circuit of a semiconductor integrated circuit of one circuit module is connected to an interface circuit of a semiconductor integrated circuit of another circuit module through a signal line. Also, each of the circuit modules is provided with a power source circuit, and is operated with a power supply voltage output therefrom. Namely, each of the circuit modules is independently operated by its power source circuit. In this case, the power supply voltages output from the power source circuits are assumed to be at the same level.

In the operation of an electronic apparatus, when one of the circuit modules is not used, it is powered OFF to reduce power consumption in the electronic apparatus. At this time, the signal line of the powered-OFF circuit module is electrically floated, so that a malfunction may occur in a powered-ON circuit module to which the signal line of the powered-OFF circuit module is connected. In order to prevent the occurrence of a malfunction, each of the interface circuits contains a pull-up resistor for pulling up a potential of the signal line of the powered-OFF circuit module.

Nevertheless, the potential of the signal line cannot be adequately pulled up to a desirable high level, because a current flows from the power source circuit of the powered-ON circuit module into the power source circuit of the powered-OFF circuit module through the pull-up resistor of the powered-ON circuit module, the signal line and the pull-up resistor of the powered-OFF circuit module.

In order to prevent the flowing of current from the power source circuit of the powered-ON circuit module into the power source circuit of the powered-OFF circuit module, it has been proposed to provide a blocking diode between the power source circuit and the pull-up resistor, as disclosed in, for example, JP-A-S62-256118, JP-A-H06-149429, JP-A-2000-099219, JP-A-2002-169635, JP-A-2003-133944 and JP-A-2003-037490.

The pull-up resistor may be formed as a diffusion sheet resistance element in a semiconductor substrate of the interface circuit. In this case, it is impossible to adequately pull up the potential of the signal line to a desirable high level by the diffusion sheet resistance element, because a leakage flows in the vicinity of the diffusion sheet resistance element formed in the semiconductor substrate, as discussed in detail hereinafter.

### SUMMARY OF THE INVENTION

Therefore, an object of the present invention is to provide a semiconductor integrated circuit having an interface circuit containing a pull-up resistor and a blocking diode, in which the blocking diode is associated with the pull-up resistor so that the above-mentioned leakage current can be suppressed.

Another object of the present invention is to provide a circuit module including such a semiconductor integrated circuit.

Yet another object of the present invention is to provide an electronic apparatus which is constituted by circuit modules each including such a semiconductor integrated circuit.

In accordance with a first aspect of the present invention, there is provided a semiconductor integrated circuit, which comprises an interface circuit adapted to be connected to a power supply line, a signal line connected to the interface circuit, a pull-up resistor connected to the power supply line at one terminal thereof, and a blocking diode having an anode and a cathode which are connected to another terminal of the pull-up resistor and the signal line, respectively.

The pull-up resistor may be formed as a diffusion sheet resistance element in a semiconductor substrate of the interface circuit.

When the semiconductor substrate features a first conductivity type, the blocking diode may be constituted by a second conductivity type well region formed in the semiconductor substrate, and a first conductivity type impurity diffusion region formed in the second conductivity type well region.

When the semiconductor substrate includes an unused first type metal oxide semiconductor (MOS) transistor due to a formation of the semiconductor substrate by a master slice method, the blocking diode may be defined by utilizing the unused first type MOS transistor.

The interface circuit may be formed as one of an input/output interface circuit, an input interface circuit and an output interface circuit.

In accordance with a second aspect of the present invention, there is provided a circuit module comprising a semiconductor integrated circuit having an interface circuit incorporated therein, and a power supply line connected to the semiconductor integrated circuit. The interface circuit comprises a signal line connected thereto, a pull-up resistor connected to the power supply line at one terminal thereof, and a blocking diode having an anode and a cathode which are connected to another terminal of the pull-up resistor and the signal line, respectively.

In accordance with a third aspect of the present invention, there is provided an electronic apparatus comprising: a first circuit module including a first semiconductor integrated circuit having a first interface circuit incorporated therein, and a first power supply line connected to the first semiconductor integrated circuit; and a second circuit module including a second semiconductor integrated circuit having a second interface circuit, and a second power supply line connected to the second semiconductor integrated circuit; and a signal line connected between the first and second interface circuits. The first interface circuit includes a first pull-up resistor connected to the first power supply line at one terminal thereof, and a first blocking diode having an anode and a cathode which are connected to another terminal of the first pull-up resistor and the signal line, respectively. The second interface circuit includes a second pull-up resistor connected to the second power supply line at one terminal thereof, and a second blocking diode having an anode and a cathode which are connected to another terminal of the second pull-up resistor and the signal line, respectively.

### BRIEF DESCRIPTION OF THE DRAWINGS

The above objects and other objects will be more clearly understood from the description set forth below, with reference to the accompanying drawings, wherein:

FIG. 1 is a block circuit diagram of a first prior art electronic apparatus;

FIG. 2 is a block circuit diagram of a second prior art electronic apparatus;

FIG. 3 is a block circuit diagram of a third prior art electronic apparatus;

FIG. 4 is a block circuit diagram of a fourth prior art electronic apparatus;

FIG. 5A is a partial plan view of one of semiconductor substrates included in the main and sub circuit modules of FIG. 4;

FIG. 5B is a partial cross-sectional view taken the line V-V of FIG. 5A;

FIG. 6 is a partial cross-sectional view of the diode of FIG. 4;

FIG. 7 is a partial cross-sectional view of the semiconductor substrates included in the main and sub circuit modules of FIG. 4;

FIG. 8 is a block circuit diagram of a first embodiment of an electronic apparatus according to the present invention;

FIG. 9 is a partial cross-sectional view of semiconductor substrates included in the main and sub circuit modules of the electronic apparatus of FIG. 8;

FIG. 10 is a partial cross-sectional view of one of the semiconductor substrates included in the main and sub circuit modules of FIG. 8; and

FIG. 11 is a block circuit diagram of a second embodiment of the electronic apparatus according to the present invention.

### DESCRIPTION OF THE PREFERRED EMBODIMENTS

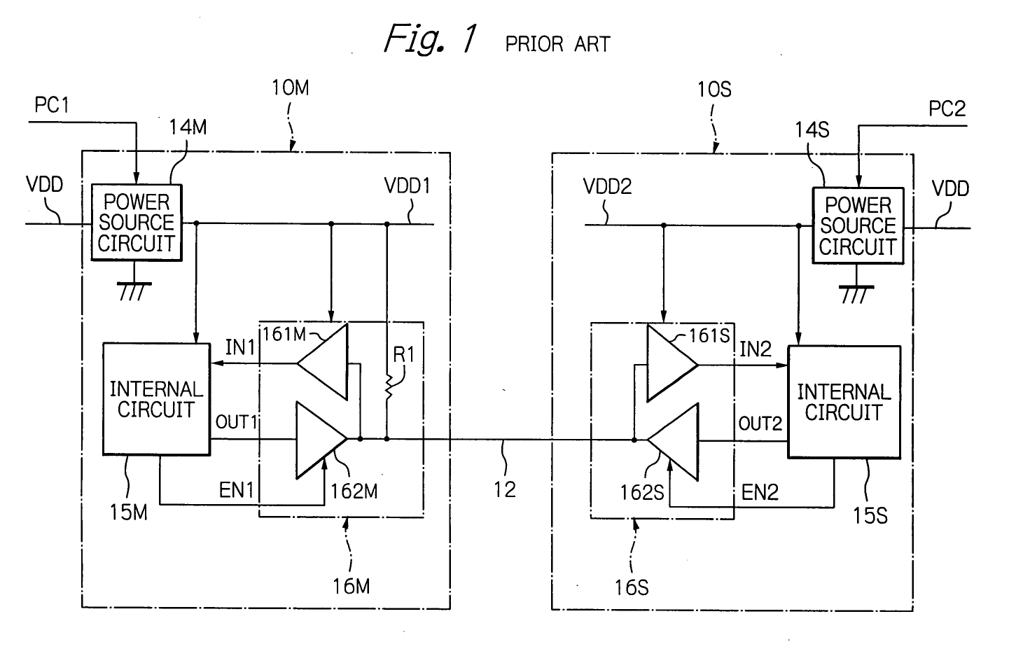

Before a description of the preferred embodiments of the present invention, for better understanding of the present invention, prior art electronic apparatuses will be now explained with reference to FIGS. 1, 2, 3, 4, 5A, 5B and 6.

In FIG. 1, which illustrates a first prior art electronic apparatus, a main circuit module 10M and a sub circuit module 10S are connected to each other through a signal line 12.

The main circuit module 10M includes a semiconductor integrated circuit which is formed by a power source circuit 14M, an internal circuit 15M, and an input/output interface circuit 16M which includes an input buffer 161M, an output buffer 162M and a pull-up resistor R1.

The power source circuit 14M is connected to a power supply source (not shown) of the electronic apparatus through a power supply line VDD, and is controlled by a power control signal PC1 which is output from a control circuit (not shown) of the electronic apparatus, to apply a power supply voltage to the internal circuit 15M and the input/output interface circuit 16M through a power supply line VDD1.

The power control signal PC1 is changed between a low level and a high level. For example, when the power control signal PC1 is at the low level, the main circuit module 10M is put into a powered-OFF state, i.e. the internal circuit 15M and the input/output interface circuit 16M are powered OFF. When the power control signal PC1 is at the high level, the main circuit module 10M is put into a powered-ON state, i.e. the internal circuit 15M and the input/output interface circuit 16M are powered ON.

The input buffer 161M is connected to the signal line 12 at an input terminal thereof, and an output terminal of the input buffer 161M is connected to the internal circuit 15M. Namely, the input buffer 161M receives a signal from the signal line 12 to thereby generate an output signal, which is transmitted as an input signal IN1 to the internal circuit 15M.

The output buffer 162M is connected to the signal line 12 at an output terminal thereof, and an input terminal of the output buffer 162M is connected to the internal circuit 15M. Namely, the output buffer 162M receives an output signal OUT1 from the internal circuit 15M to thereby generate an output signal, which is transmitted to the sub circuit module 10S through the signal line 12.

Also, the output buffer 162M is controlled by an enable signal EN1 which is output from the internal circuit 15M, and the enable signal EN1 is changed between a low level and a high level. For example, when the enable signal EN1 is at the low level, the output buffer 162M is disabled. When the enable signal EN1 is at the high level, the output buffer 162M is enabled.

The pull-up resistor R1 is connected to the signal line 12 at one terminal thereof, and the other terminal of the pull-up resistor R1 is connected to the power source circuit 14M through the power supply line VDD1.

The sub circuit 10S has a similar structure to the main circuit 10M. That is, the sub circuit 10S includes a power source circuit 14S, an internal circuit 15S and an input/output interface circuit 16S, which correspond to the power source circuit 14M, the internal circuit 15M and the input/output interface circuit 16M, respectively, of the main circuit 10M. In this case, however, the input/output interface circuit 16S includes only an input buffer 161S and an output buffer 162S with no pull-up resistor. In more detail, the power source circuit 14S is controlled by a power control signal PC2 to apply a power supply voltage to the internal circuit 15S and the input/output interface circuit 16S through a power supply line VDD2. Also, the input buffer 161S receives a signal from the signal line 12 to thereby transmit an input signal IN2 to the internal circuit 15S. Further, the output buffer 162S is controlled by an enable signal EN2 from the internal circuit 15S, to thereby receive an output signal OUT2 and generate an output signal which is transmitted to the signal line 12.

Note, in the electronic apparatus of FIG. 1, the level of the power supply voltage applied from the power source circuit 14M to the power supply line VDD1 is substantially the same as the level of the power supply voltage applied from the power source circuit 14S to the power supply line VDD2. Namely, the main and sub circuit modules 10M and 10S are operated with the same level power supply voltage.

In the operation of the electronic apparatus of FIG. 1, when the sub module circuit 10S is not used, the internal circuit 15S and the input/output interface circuit 16S are powered OFF by the power control signal PC2 to reduce power consumption in the electronic apparatus. In this case, if the pull-up resistor R1 is not provided in the input/output interface circuit 16M, the signal line 12 is in an electrically-floating state due to the powered-OFF state of the internal circuit 15S and the input/output interface circuit 16S while the enable signal EN1 is at the low level, so that a malfunction may occur in the main circuit module 10M. However, in reality, a potential of the signal line 12 is pulled up to by the pull-up resistor R1, and thus it is possible to stably maintain the potential of the signal line 12 at a desirable high level during the powered-OFF state of the sub circuit module 10S, resulting in prevention of occurrence of the malfunction in the main circuit module 10M.

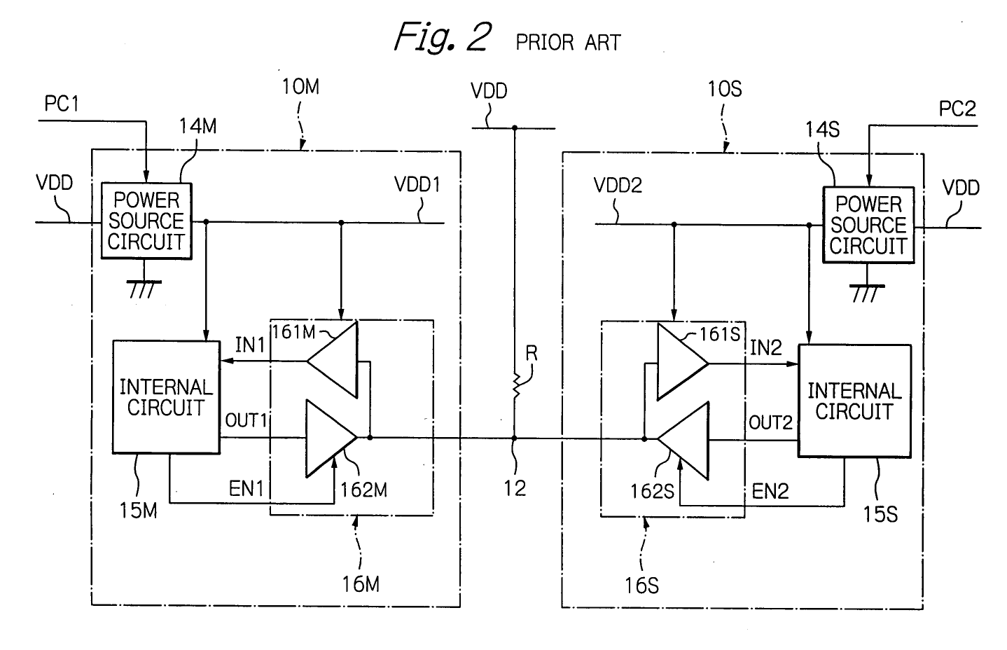

FIG. 2 shows a second prior art electronic apparatus, which is identical to the electronic apparatus of FIG. 1 except that an external pull-up resistor R is substituted for the pull-up resistor R1 of FIG. 1.

The external pull-up resistor R is mounted on a printed wiring board (not shown) on which either the main circuit module 10M or both the main and sub circuit modules 10M and 10S are mounted. Note, the pull-up resistor R1 of FIG. 1 may be formed as a diffusion sheet resistance element in a semiconductor substrate, whereas the external pull-up resistor R of FIG. 2 may be formed as a discrete resistance element. The external pull-up resistor R is connected to the signal line 12 at one terminal of thereof, and the other terminal of the external pull-up resistor R is connected to the power supply line VDD connected to the power supply source (not shown) of the electronic apparatus.

The electronic apparatus of FIG. 2 is arranged on the assumption that one of the main and sub circuit modules 10M and 10S is put into a powered-OFF state by a corresponding power control signal PC1 (PC2) to reduce power consumption in the electronic apparatus, if necessary.

Similar to the electronic apparatus of FIG. 1, while the internal circuit 15S and the input/output interface circuit 16S of the sub circuit module 10S are powered OFF by the power control signal PC2, it is possible to stably maintain a potential of the signal line 12 at a desirable high level by the external pull-up resistor R, resulting in prevention of occurrence of a malfunction in the main circuit module 10M. On the other hand, while the internal circuit 15M and the input/output interface circuit 16M of the main circuit module 10M are powered OFF by the power control signal PC1, it is possible to stably maintain a potential of the signal line 12 at a desirable high level due to the provision of the external pull-up resistor R, resulting in prevention of occurrence of a malfunction in the sub circuit module 10S.

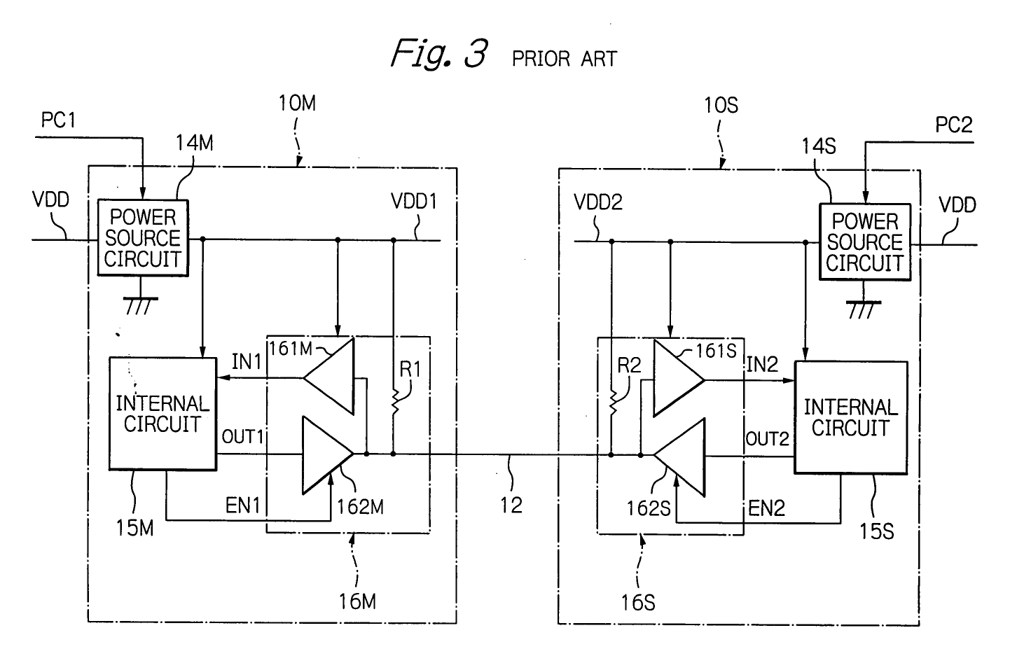

FIG. 3 shows a third prior art electronic apparatus, which is identical to the electronic apparatus of FIG. 1 except that the input/output interface circuit 16S of the sub circuit module 10S is provided with a pull-up resistor R2.

The pull-up resistor R2 is connected to the signal line 12 at one terminal of thereof, and the other terminal of the pull-up resistor R2 is connected to the power source circuit 14S through the power supply line VDD2. Note, each of the pull-up resistors R1 and R2 may be formed as a diffusion sheet resistance element in a semiconductor substrate.

Similar to the electronic apparatus of FIG. 2, the electronic apparatus of FIG. 3 is arranged on the assumption that one of the main and sub circuit modules 10M and 10S is put into a powered-OFF state by a corresponding power control signal PC1 (PC2) to reduce power consumption in the electronic apparatus, if necessary. Namely, during the powered-OFF state of the sub circuit module 10S, a potential of the signal line 12 is pulled up by the pull-up resistor R1, and, during the powered-OFF state of the main circuit module 10M, a potential of the signal line 12 is pulled up by the pull-up resistor R2.

Nevertheless, in the electronic apparatus of FIG. 3, it is impossible to adequately pull up a potential of the signal line 12 to a desirable high level by the pull-up resistor R1 (R2) for the reasons discussed in detail below.

In the electronic apparatus of FIG. 3, while the internal circuit 15S and the input/output interface circuit 16S of the sub circuit module 10S are powered OFF by the power control signal PC2, a current flows from the power source circuit 14M into the power source circuit 14S through the power supply line VDD1, the pull-up resistor R1, the signal line 12, the pull-up resistor R2 and the power supply line VDD2. On the other hand, while the internal circuit 15M and the input/output interface circuit 16M of the main circuit module 10M are powered OFF by the power control signal PC1, a current flows from the power source circuit 14S into the power source circuit 14M through the power supply line VDD2, the pull-up resistor R2, the signal line 12, the pull-up resistor R1 and the power supply line VDD1. Thus, it is impossible to adequately pull up the potential of the signal line 12 to the desirable high level by the pull-up resistor R1 (R2) during either the powered-OFF state of the main circuit module 10M or the powered-OFF state of the sub circuit module 10S.

In the electronic apparatus of FIG. 3, it has been proposed to provide a blocking diode between the pull-up resistor R1 (R2) and the corresponding power source circuit (14M, 14S) to block the flow of current through the pull-up resistor R1 (R2), as disclosed in, for example, JP-A-S62-256118, JP-A-H06-149429, JP-A-2000-099219, JP-A-2002-169635, JP-A-2003-133944 and JP-A-2003-037490.

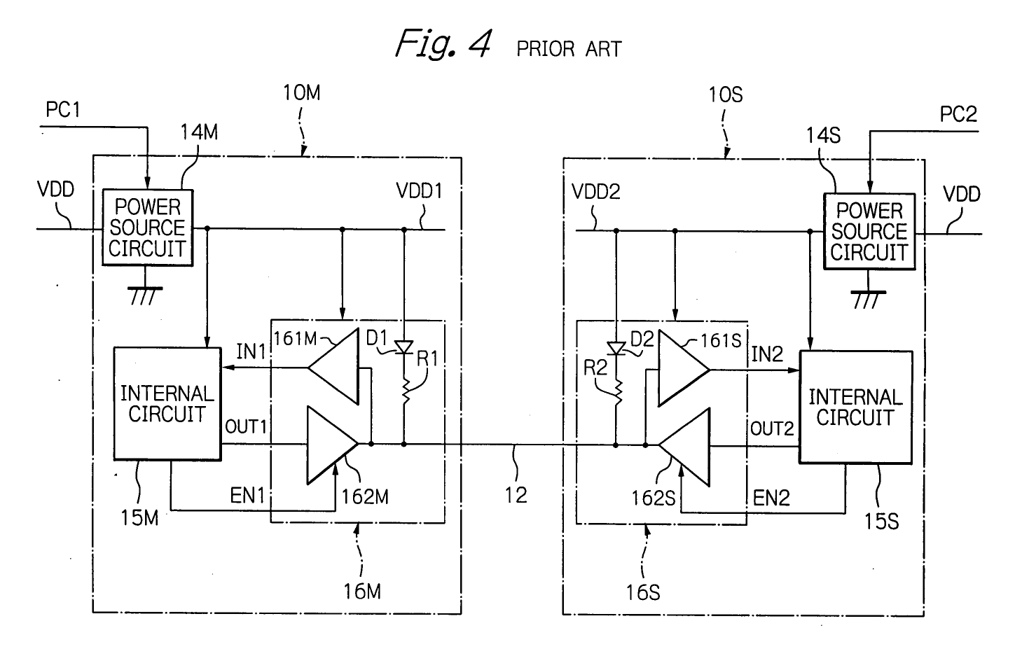

FIG. 4 shows a fourth prior art electronic apparatus which is arranged such that the above-mentioned current in FIG. 3 can be prevented.

The electronic apparatus of FIG. 4 is identical to the electronic apparatus of FIG. 3 except that two blocking diodes D1 and D2 are associated with the pull-up resistors R1 and R2, respectively.

In particular, the blocking diode D1 is formed in the semiconductor substrate of the input/output interface circuit 16M so as to be provided between the pull-up resistor R1 and the power source circuit 14M. Namely, the anode of the blocking diode D1 is connected to the power supply line VDD1, and the cathode of the blocking diode D1 is connected to the pull-up resistor R1. Similarly, the blocking diode D2 is formed in the semiconductor substrate of the input/output interface circuit 16S so as to be provided between the pull-up resistor R2 and the power source circuit 14S. Namely, the anode of the blocking diode D2 is connected to the power supply line VDD2, and the cathode of the blocking diode D2 is connected to the pull-up resistor R2.

In the electronic apparatus of FIG. 4, during the powered-OFF state of the sub circuit module 10S, the current flowing through the pull-up resistor R1 is blocked off by the blocking diode D1. Similarly, during the powered-OFF state of the main circuit module 10M, the current flowing through the pull-up resistor R2 is blocked off by the blocking diode D2. Nevertheless, the current flowing through the pull-up resistor R1 (R2) cannot be virtually blocked off by the blocking diode D1 (D2), because a leakage current flows in the vicinity of the diffusion sheet resistance elements or pull-up resistor R1 (R2), as discussed in detail below.

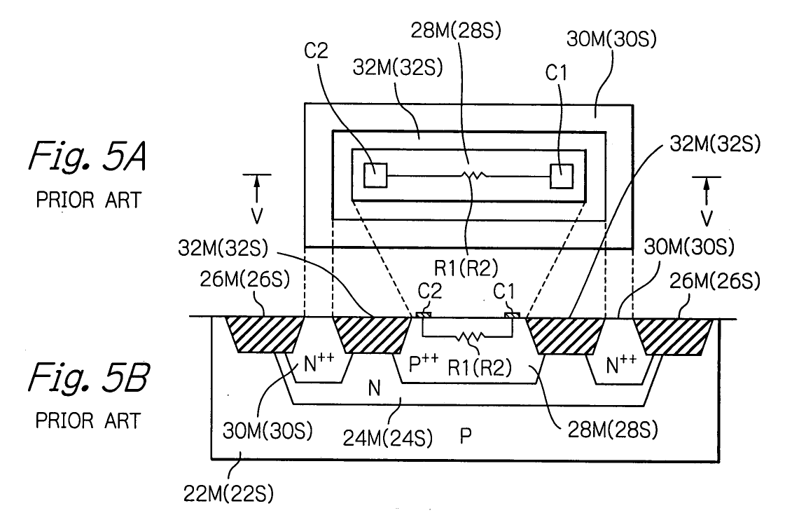

FIG. 5A shows an arrangement of a diffusion sheet resistance element, which is used as the pull-up resistor R1 (R2) in the electronic apparatus of FIG. 4, and FIG. 5B is a cross-sectional view taken along the line V-V of FIG. 5A.

In FIGS. 5A and 5B, a part of the semiconductor substrate of the input/output interface circuit 16M (16S) is formed as a P-type semiconductor substrate 22M (22S). An N-type well region 24M (24S) is formed in the P-type semiconductor substrate 22M (22S), and is surrounded by an isolation layer 26M (26S). A P⁺⁺-type impurity diffusion region 28M (28S) is formed in the N-type well region 24M (24S), and an N⁺⁺-type impurity diffusion region 30M (30S) is formed in the N-type well region 24M (24S) so as to surround the P⁺⁺-type impurity diffusion region 28M (28S), with the regions 28M (28S) and 30M (30S) being isolated from each other by an isolation layer 32M (32S) formed in the N-type well region 24M (24S) therebetween.

Also, two pads or contacts C1 and C2 are formed on the P⁺⁺-type impurity diffusion region 28M (28S) so as to be spaced from each other by a suitable distance, and thus a diffusion sheet resistance element, which is also indicated by reference R1 (R2), is defined between the contacts C1 and C2, as symbolically shown in FIGS. 5A and 5B, with the contacts C1 and C2 forming the terminals of the diffusion sheet resistance element R1 (R2).

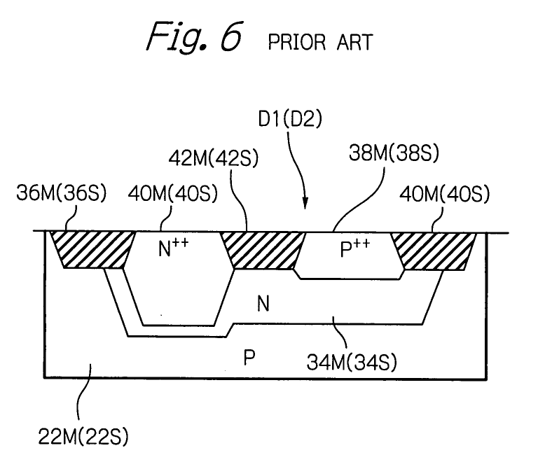

Also, in FIG. 6, which shows the blocking diode D1 (D2) of FIG. 4, the blocking diode D1 (D2) is formed in the P-type semiconductor substrate 22M (22S) of the input/output interface circuit 16M (16S). Namely, the blocking diode D1 (D2) includes an N-type well region 34M. (34S) formed in the P-type semiconductor substrate 22M (22S) and surrounded by an isolation layer 36M (36S), a P⁺⁺-type impurity diffusion region (anode) 38M (38S) formed in the N-type well region 34M (34S), and an N⁺⁺-type impurity diffusion region (cathode) 40M (40S) formed in the N-type well region 34M (34S), with the regions 38M (38S) and 40M (40S) being isolated from each other by an isolation layer 42M (42S) formed in the N-type well region 34M (34S) therebetween.

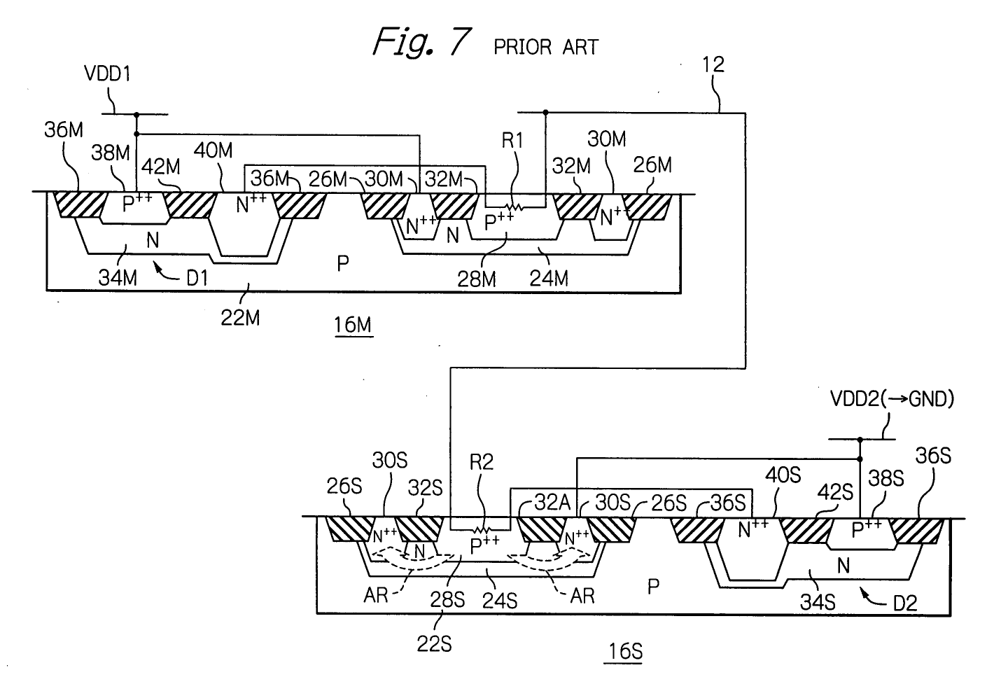

In FIG. 7, the P-type semiconductor substrate 22M of the input/output interface circuit 16M and the P-type semiconductor substrate 22S of the input/output interface circuit 16S of FIG. 4 are illustrated.

In the input/output interface circuit 16M, the P⁺⁺-type impurity diffusion region (anode) 38M of the blocking diode D1 is connected to the power supply line VDD1, the N⁺⁺-type impurity diffusion region (cathode) 40M of the blocking diode D1 is connected to one terminal (C2) of the pull-up R1, and the other terminal (C1) of the pull-up resistor R1 is connected to the signal line 12. Also, the N⁺⁺-type impurity diffusion region 30M is connected to the power supply line VDD1 so that a P-N junction between the P⁺⁺-type impurity diffusion region 28M and the N-type well region 24M is reversely biased, thereby ensuring a proper function of the pull-up resistor R1 during the powered-ON state of the main circuit module 10M.

Similarly, in the input/output interface circuit 16S, the P⁺⁺-type impurity diffusion region (anode) 38S of the blocking diode D2 is connected to the power supply line VDD2, the N⁺⁺-type impurity diffusion region (cathode) 40S of the blocking diode D2 is connected to one terminal (C1) of the pull-up resistor R2, and the other terminal (C2) of the pull-up resistor R2 is connected to the signal line 12. Also, the N⁺⁺-type impurity diffusion region 30S is connected to the power supply line VDD2 so that a P-N junction between the P⁺⁺-type impurity diffusion region 28S and the N-type well region 24S is reversely biased, thereby ensuring a proper function of the pull-up resistor R2 during the powered-ON state of the sub circuit module 10S.

In FIG. 7, when the sub circuit module 10S is put into a powered-OFF state so that the power supply line VDD2 is grounded, a current flows from the power source circuit 14M (FIG. 4) into the pull-up resistor R2 through the power supply line VDD1, the blocking diode D1 and the signal line 12. At this time, a leakage current flows in the vicinity of the pull-up resistor R2, as conceptually and symbolically represented by arrows AR in FIG. 7. Namely, during the powered-OFF state of the sub circuit module 10S, a potential of the N-type well region 24S is lowered to the ground level (GND), and thus a forwardly-biased parasitic diode is produced at a P-N junction between the P⁺⁺-type impurity diffusion region 28S and the N-type well region 24S, so that the leakage current flows in the vicinity of the pull-up resistor R2.

Note, the same is true for the case where the main circuit module 10M is put into a powered-OFF state. Namely, during the powered-OFF state of the main circuit module 10M, a leakage current flows in the vicinity of the pull-up resistor R1.

Accordingly, as stated above, in the electronic apparatus of FIG. 4, the current flowing into the pull-up resistor R1 (R2) cannot be virtually blocked off by the blocking diode R1 (R2). As a result, the potential of the signal line 12 cannot be adequately pulled up to the desirable high level.

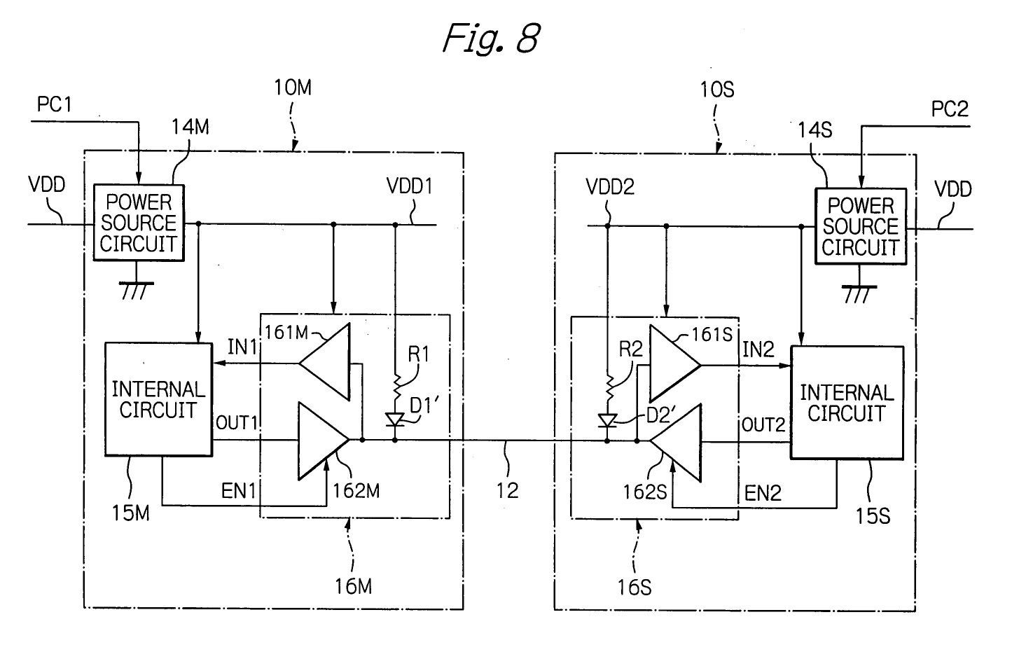

In FIG. 8, which shows a first embodiment of an electronic apparatus according to the present invention, two blocking diodes D1′ and D2′ are substituted for the blocking diodes D1 and D2 of FIG. 4.

In particular, the blocking diode D1′ is formed in the semiconductor substrate of the input/output interface circuit 16M so as to be provided between the pull-up resistor R1 and the signal line 12. Namely, the anode of the blocking diode D1′ is connected to the pull-up resistor R1, and the cathode of the blocking diode D1′ is connected to the signal line 12.

Similarly, the blocking diode D2′ is formed in the semiconductor substrate of the input/output interface circuit 16S so as to be provided between the pull-up resistor R2 and the signal line 12. Namely, the anode of the blocking diode D2′ is connected to the pull-up resistor R2, and the cathode of the blocking diode D2′ is connected to the signal line 12.

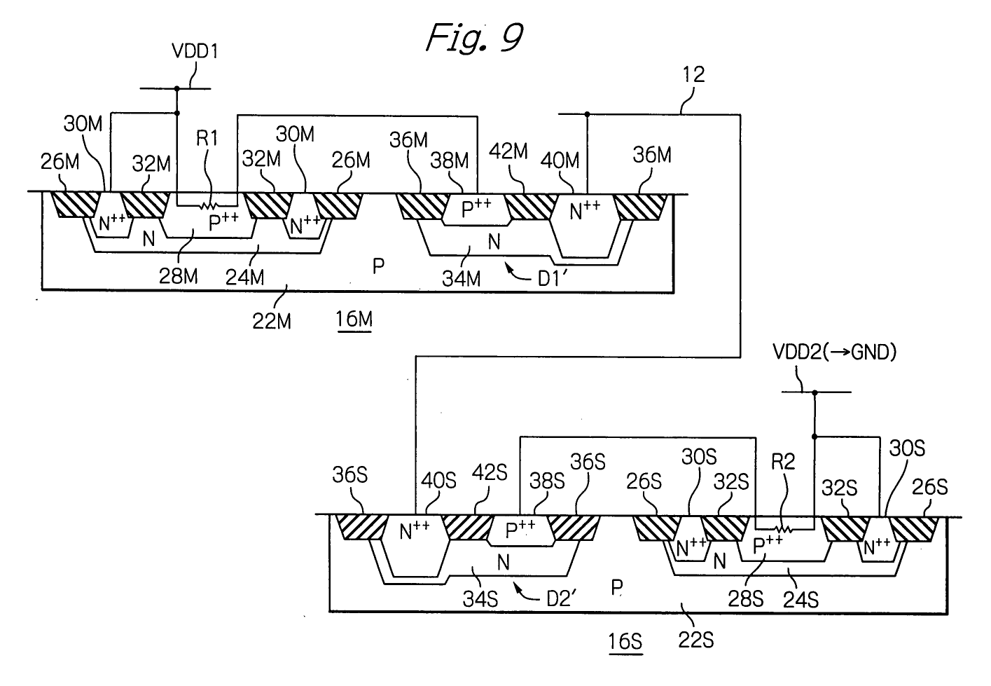

As shown in FIG. 9 corresponding to FIG. 7, the respective pull-up resistor R1 and R2 and the respective blocking diode D1′ and D2′ are formed in the semiconductor substrates 22M and 22S of the input/output interface circuits 16M and 16S.

In the input/output interface circuit 16M, the diffusion sheet resistance element or pull-up resistor R1 is connected to the power supply line VDD1 at one terminal (C2) thereof, the other terminal (C1) of the pull-up resistor R1 is connected to the P⁺⁺-type impurity diffusion region (anode) 38M of the blocking diode D1′, and the N⁺⁺-type impurity diffusion region (cathode) 40M of the blocking diode D1′ is connected to the signal line 12. Also, the N⁺⁺-type impurity diffusion region 30M is connected to the power supply line VDD1 so that a P-N junction between the P⁺⁺-type impurity diffusion region 28M and the N-type well region 24M is reversely biased, thereby ensuring a proper function of the pull-up resistor R1 during the powered-ON state of the main circuit module 10M.

Similarly, in the input/output interface circuit 16S, the diffusion sheet resistance element or pull-up resistor R2 is connected to the power supply line VDD2 at one terminal (C1) thereof, the other terminal (C2) of the pull-up resistor R2 is connected to the P⁺⁺-type impurity diffusion region (anode) 38S of the blocking diode D2′, and the N⁺⁺-type impurity diffusion region (cathode) 40S of the blocking diode D2′ is connected to the signal line 12. Also, the N⁺⁺-type impurity diffusion region 30S is connected to the power supply line VDD2 so that a P-N junction between the P⁺⁺-type impurity diffusion region 28S and the N-type well region 24S is reversely biased, thereby ensuring a proper function of the pull-up resistor R2 during the powered-ON state of the main circuit module 10S.

In FIG. 9, while the sub circuit module 10S is put into a powered-OFF state by the power control signal PC2 so that the power supply line VDD2 is grounded, since the blocking diode D2′ is reversely biased, it is possible to completely block off a current flowing from the power source circuit 14M into the signal line 12 through the power supply line VDD1, the pull-up resistor R1, and the blocking diode D1′. The same is true for the case where the main circuit module 10M is put into a powered-OFF state.

In short, there is no leakage current in the vicinity of the pull-up resistor R1 (R2), as shown by the arrows AR in FIG. 7. Therefore, it is possible to adequately pull up the potential of the signal line 12 to a desirable high level while either the main circuit module 10M or the sub circuit module 10S is put into the powered-OFF state.

In a case where the semiconductor integrated circuits of the main and sub circuit modules 10M and 10S are produced by using a well known master slice method, each of the semiconductor integrated circuits may include P-channel type metal oxide semiconductor (MOS) transistors as unused elements. In this case, it is possible to utilize each of the P-channel type MOS transistors as the blocking diode D1′ (D2′).

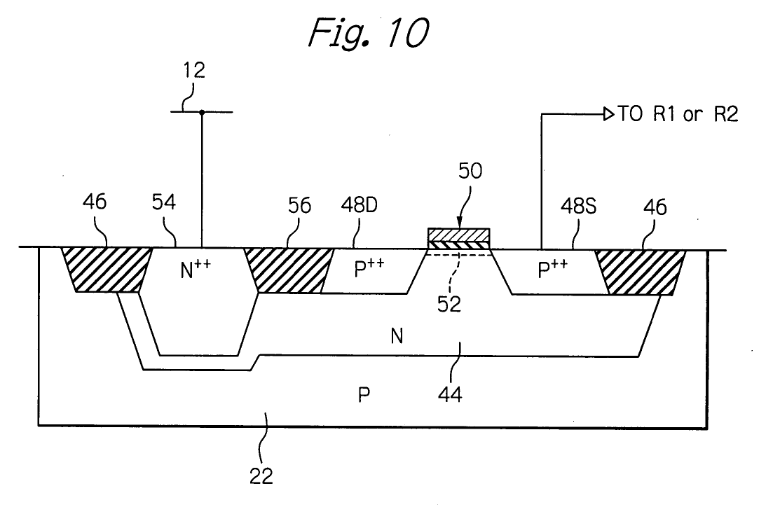

FIG. 10 representatively shows one of the P-channel type MOS transistors formed in the P-type semiconductor substrate 22M (22S) of the input/output interface circuit 16M (16S) of FIG. 9.

The P-channel type MOS transistor includes an N-type well region 44 formed in the P-type semiconductor device 22 and surrounded by an isolation layer 46, a P⁺⁺-type source region 48S formed in the N-type well region 44, a P⁺⁺-type drain region 48D formed in the N-type well region 44, and a gate electrode structure 50 formed on a surface of the N-type well region 44 so as to bridge a space between the source region 48S and the drain region 48D to thereby define a channel region 52 therebetween. Also, an N⁺⁺-type impurity diffusion region 54 is formed in the N-type well region 44, and is isolated from the drain region 48D by an isolation layer 56 formed in the N-type well region 44 therebetween.

When the P-channel type MOS transistor is utilized as the blocking diode D1′ (D2′), the source region 48S is connected to the diffusion sheet resistance element R1 (R2) formed in the P-type semiconductor substrate 22M (22S), and the N⁺⁺-type impurity diffusion region 54 is connected to the signal line 12, as shown in FIG. 10. With this arrangement, a P-N junction between the source region 48S and the N-type well region 44 serves as the blocking diode D1′ (D2′).

Optionally, a P-N junction between the drain region 48D and the N-type well region 44 may be used as the blocking diode D1′ (D2′). Of course, in this case, the drain region 48D is connected to the diffusion sheet resistance element R1 (R2) formed in the P-type semiconductor substrate 22M (22S).

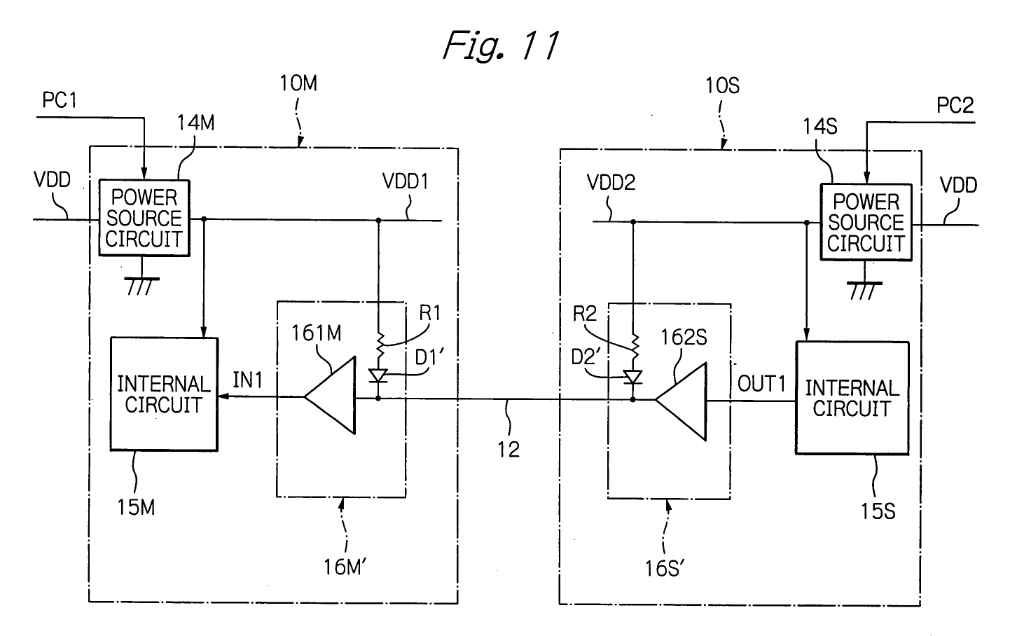

In FIG. 11, which shows a second embodiment of the electronic apparatus according to the present invention, respective input interface circuit 16M′ and output interface circuit 16S′ are substituted for the input/output interface circuits 16M and 16S of FIG. 8.

Similar to the above-mentioned first embodiment of FIG. 8, the blocking diode D1′ (D2′) is connected to the pull-up resistor R1 (R2) and the signal line 12, and thus there is no leakage current in the vicinity of the pull-up resistor R1 (R2), as shown by the arrow AR in FIG. 7. Namely, during the powered-OFF state of the sub circuit module 10S, it is possible to adequately pull up the potential of the signal line 12 to a desirable high level by the pull-up resistor R1. Similarly, during the powered-OFF state of the main circuit module 10M, it is possible to adequately pull up the potential of the signal line 12 to a desirable high level by the pull-up resistor R2.

In the above-mentioned first and second embodiments, the potential of the signal line 12 cannot be pulled up to the power supply voltage applied to the power supply line VDD1 (VDD2) by the pull-up resistor R1 (R2), due to the provision of the blocking diode D1′ (D2′). Namely, the potential of the signal line 12, which can be pulled up by the pull-up resistor R1 (R2), is lower than the power supply voltage by a forward voltage (V_{f}) of the blocking diode D1′ (D2′). However, the forward voltage (V_{f}) of the blocking diode D1′ (D2′) is very small, and thus the lowering of the potential of the signal line 12 by the forward voltage (V_{f}) can be neglectable.

Finally, it will be understood by those skilled in the art that the foregoing description is of preferred embodiments of the device, and that various changes and modifications may be made to the present invention without departing from the spirit and scope thereof.

1. A semiconductor integrated circuit comprising:
an interface circuit adapted to be connected to a power supply line;
a signal line connected to said interface circuit;
a pull-up resistor connected to said power supply line at one terminal thereof; and
a blocking diode having an anode and a cathode which are connected to another terminal of said pull-up resistor and said signal line, respectively.

2. The semiconductor integrated circuit as set forth in claim 1, wherein said pull-up resistor comprises a diffusion sheet resistance element.

3. The semiconductor integrated circuit as set forth in claim 1, wherein said blocking diode is formed in a semiconductor substrate featuring a first conductivity type, and includes a second conductivity type well region formed in said semiconductor substrate, and a first conductivity type impurity diffusion region formed in said second conductivity type well region.

4. The semiconductor integrated circuit as set forth in claim 3, wherein said semiconductor substrate includes an unused first type metal oxide semiconductor (MOS) transistor due to a formation of the semiconductor substrate by a master slice method, and wherein said blocking diode is defined by utilizing the unused first type MOS transistor.

5. The semiconductor integrated circuit as set forth in claim 1, wherein said interface circuit comprises an input/output interface circuit.

6. The semiconductor integrated circuit as set forth in claim 1, wherein said interface circuit comprises an input interface circuit.

7. The semiconductor integrated circuit as set forth in claim 1, wherein said interface circuit comprises an output interface circuit.

8. A circuit module comprising:
a semiconductor integrated circuit having an interface circuit incorporated therein;
a power supply connected to said semiconductor integrated circuit;
wherein said interface circuit comprises:
a signal line;
a pull-up resistor connected to said power supply line at one terminal thereof; and
a blocking diode having an anode and a cathode which are connected to another terminal of said pull-up resistor and said signal line, respectively.

9. The circuit module as set forth in claim 8, wherein said pull-up resistor comprises a diffusion sheet resistance element.

10. The circuit module as set forth in claim 8, wherein said blocking diode is formed in a semiconductor substrate featuring a first conductivity type, and includes a second conductivity type well region formed in said semiconductor substrate, and a first conductivity type impurity diffusion region formed in said second conductivity type well region.

11. The circuit module as set forth in claim 10, wherein said semiconductor substrate includes an unused first type MOS transistor due to a formation of the semiconductor substrate by a master slice method, and wherein said blocking diode is defined by utilizing the unused first type MOS transistor.

12. An electronic apparatus comprising:
a first circuit module including a first semiconductor integrated circuit having a first interface circuit incorporated therein, and a first power supply line connected to said first semiconductor integrated circuit;
a second circuit module including a second semiconductor integrated circuit having a second interface circuit, and a second power supply line connected to said second semiconductor integrated circuit; and
a signal line connecting between said first and second interface circuits,
wherein said first interface circuit includes:
a first pull-up resistor connected to said first power supply line at one terminal thereof; and
a first blocking diode having an anode and a cathode which are connected to another terminal of said first pull-up resistor and said signal line, respectively, and
wherein said second interface circuit includes:
a second pull-up resistor connected to said second power supply line at one terminal thereof; and
a second blocking diode having an anode and a cathode which are connected to another terminal of said second pull-up resistor and said signal line, respectively.

13. The electronic apparatus as set forth in claim 12, wherein a power supply voltage applied to said first power supply line is substantially equal to a power supply voltage applied to said second power supply line.

14. The electronic apparatus as set forth in claim 12, wherein each of said first and second pull-up resistors comprises a diffusion sheet resistance element.

15. The electronic apparatus as set forth in claim 12, wherein each of said first and second blocking diodes is formed in a semiconductor substrate featuring a first conductivity type, and includes a second conductivity type well region formed in said semiconductor substrate, and a first conductivity type impurity diffusion region formed in said second conductivity type well region.

16. The electronic apparatus as set forth in claim 15, wherein said semiconductor substrate includes an unused first type MOS transistor due to a formation of the semiconductor substrate by a master slice method, and wherein each of said first and second blocking diodes is defined by utilizing the unused first type MOS transistor.
